(19) United States
(12) Patent Application Publication
(10) Pub. No.: US 2025/0141447 A1
(43) Pub. Date: May 1, 2025

(54) MODULAR CIRCUIT BOARD, NON-CONTACT SWITCH SYSTEM, AND SWITCH DETECTION METHOD

(71) Applicant: DARWIN PRECISIONS CORPORATION, Hsinchu County (TW)

(72) Inventors: RAN-SHIOU YOU, Hsinchu County (TW); YA HAN KO, Hsinchu County (TW); Chia Tsun Huang, Hsinchu County (TW); Chih-hung Liu, Hsinchu County (TW)

(21) Appl. No.: 18/809,384

(22) Filed: Aug. 20, 2024

(30) Foreign Application Priority Data
Oct. 30, 2023 (TW) 112141611

(51) Int. Cl. H03K 17/955; H03K 17/945; H05K 1/18

(52) U.S. Cl. CPC H03K 17/955; H05K 1/181; H03K 2017/9455; H05K 2201/10053

(57) ABSTRACT

A modular circuit board, a non-contact switch system, and a switch detection method are provided. The non-contact switch system includes multiple modular circuit boards. The modular circuit board includes: a non-contact switch set configured to receive a sensing signal of a sensed target; and a processing unit configured to perform a general program. The processing unit includes a detection unit, and the detection unit includes a first common lead. The general program includes a single-board detection process and a multi-board detection process. The single-board detection process includes: determining whether only one non-contact switch receives the sensing signal, and entering the multi-board detection process if a determining result is yes; or providing, by the detection unit, a marked potential if the determining result is no. The multi-board detection process includes: determining whether a first interconnected potential of the first common lead is the marked potential.

### FIELD OF THE INVENTION

The present invention relates to a modular circuit board, a non-contact switch system, and a switch detection method, and more particularly to a modular circuit board, a non-contact switch system, and a switch detection method in which the non-contact switch system includes multiple modular circuit boards, the modular circuit boards are interconnected via common leads of detection units, and the switch detection method is used as a general program applied to the multiple modular circuit boards.

### BACKGROUND OF THE INVENTION

The non-contact switches are typically used in various control panels. Because the non-contact switch can be triggered without contact to enable a system to operate, during use, multiple non-contact switches may be touched by mistake due to a large arrange of action of an operation action on the non-contact switches, a large cross-sectional area of an object, or the like.

In addition, based on different requirements (for example, the number of switches, placement positions, or circuit board dimensions), control panels are usually assembled by combining multiple circuit boards with the same or similar circuit functions. In the related art, when a control panel is assembled by combining multiple same (or similar) circuit boards, each circuit board needs adjustment for hardware or firmware (software) to enable the main controller of the control panel (for example, a central processor configured in an operation panel separate from the foregoing circuit board) to recognize the circuit board and correctly execute an action corresponding to each circuit board.

For example, a dip switch can be toggled manually to the corresponding switch position when the firmware (software) of a circuit board is fixed, so as to distinguish the circuit board with a voltage signal of the dip switch.

For example, firmware of different versions can be separately burned onto circuit boards when the hardware of a circuit board is fixed, so as to distinguish the circuit board based on the firmware.

In summary, when the control panel of a non-contact switch system is assembled by combining multiple circuit boards, if there is no adjustment made to the hardware or firmware (software) of the circuit boards, it is difficult to determine whether the non-contact switch is touched by mistake. If the hardware or firmware (software) of the circuit board is adjusted, the replaceability between circuit boards is low. Thus, more spare circuit boards need to be prepared for replacement, or the corresponding firmware (software) needs to be reburned onto the circuit board for use.

### SUMMARY OF THE INVENTION

In view of this, the present invention provides a modular circuit board, a non-contact switch system, and a switch detection method. The switch detection method is suitable for the non-contact switch system, the non-contact switch system includes multiple modular circuit boards, a processing unit of the modular circuit board can execute a general program, and the processing unit includes a detection unit. The detection unit includes a first common lead, and the general program includes a single-board detection process and a multi-board detection process. As for the modular circuit board of the present invention, in the single-board detection process, it can be determined whether multiple non-contact switches are triggered (touched by mistake) in a non-contact switch set of a single modular circuit board. When it is determined that the non-contact switch set is touched by mistake, the detection unit provides a marked signal (for example, a first interconnected potential of the first common lead is configured as a marked potential, and the detection unit can mark the false touch with the marked signal). When it is determined that the non-contact switch set is not touched by mistake, the multi-board detection process is performed, and in the multi-board detection process, whether multiple non-contact switches are triggered (touched by mistake) in another modular circuit board is determined using the first interconnected potentials of the first common leads interconnected between multiple processing units. In this way, the replaceability of the modular circuit board can be improved significantly without the need to adjust the hardware or firmware (software) of the modular circuit board of the present invention.

The modular circuit board provided in the present invention includes: a non-contact switch set, including multiple non-contact switches configured to receive a sensing signal of a sensed target; a storage unit, configured to store a general program; and a processing unit, connected to the non-contact switch set and the storage unit, and configured to perform the general program. The processing unit includes a detection unit, and the detection unit includes a first common lead. The general program includes a single-board detection process and a multi-board detection process. The single-board detection process includes: determining whether only one non-contact switch receives the sensing signal, and entering the multi-board detection process if a determining result is yes; or determining whether only one non-contact switch receives the sensing signal, and providing, by the detection unit, a marked signal if the determining result is no. The marked signal includes a marked potential; and the multi-board detection process includes: determining whether a first interconnected potential of the first common lead is the marked potential.

In an embodiment of the present invention, the detection unit in the aforementioned modular circuit board includes a second common lead, and the single-board detection process includes: configuring the first interconnected potential of the first common lead or a second interconnected potential of the second common lead as the marked potential.

In an embodiment of the present invention, the single-board detection process in the aforementioned modular circuit board includes: disabling the non-contact switch set.

In an embodiment of the present invention, the single-board detection process in the aforementioned modular circuit board includes: enabling a prompt unit.

In an embodiment of the present invention, the single-board detection process in the aforementioned modular circuit board includes: configuring the first interconnected potential of the first common lead as a default potential.

In an embodiment of the present invention, the single-board detection process in the aforementioned modular circuit board includes: configuring the first interconnected potential of the first common lead or the second interconnected potential of the second common lead as a default potential.

In an embodiment of the present invention, the multi-board detection process in the aforementioned modular circuit board includes: disabling the non-contact switch set.

The non-contact switch system provided in the present invention includes multiple aforementioned modular circuit boards. The first common leads of multiple modular circuit boards are interconnected, and the main control unit is connected to multiple processing units.

The switch detection method provided in the present invention is suitable for the foregoing non-contact switch system. The switch detection method includes a single-board detection process and a multi-board detection process. The single-board detection process includes: determining, by the processing unit, whether only one non-contact switch receives a sensing signal of a sensed target, and entering the multi-board detection process if a determining result is yes; or determining, by the processing unit, whether only one non-contact switch receives the sensing signal, and providing, by the detection unit, a marked signal if the determining result is no. The marked signal includes a marked potential. The multi-board detection process includes: determining, by the processing unit, whether a first interconnected potential of the first common lead is the marked potential.

In summary, according to the modular circuit board, the non-contact switch system, and the switch detection method of the present invention, multiple modular circuit boards can be interconnected using common leads of the detection units. In addition, it is determined whether a modular circuit board in the single-board detection process is touched by mistake, and it is determined whether another modular circuit board in the multi-board detection process is touched by mistake. Through the foregoing architecture, the present invention does not need to distinguish the primary-secondary relationship between multiple modular circuit boards when they are combined for use and to individually burn different software/firmware onto the modular circuit boards. Instead, the same software/firmware can correspond to the parallel application of multiple circuit boards. In terms of technical beneficial effects, taking an elevator control system as an example, in a control system of a control panel of a large area, which is formed by combining multiple circuit boards, when combining the circuit boards, a client does not need to update/select software/firmware version of the circuit board and can perform mounting operation arbitrarily using the modular circuit boards of the present invention. In addition, the present invention can achieve technical beneficial effects during maintenance such as quick replacement and a decrease in maintenance time, and can significantly reduce the inventory of spare circuit boards and increase the replaceability between the modular circuit boards.

### BRIEF DESCRIPTION OF THE DRAWINGS

FIG. 1 is a block diagram of a non-contact switch system according to an embodiment of the present invention;

FIG. 2 is a schematic diagram of a floating display touch switch according to an embodiment of the present invention;

FIG. 3 is a flowchart of steps of a switch detection method (general program) according to an embodiment of the present invention; and

FIGS. 4 to 6 are schematic diagrams of a non-contact switch system being applied to an elevator system according to an embodiment of the present invention.

### DETAILED DESCRIPTION OF PREFERRED EMBODIMENTS

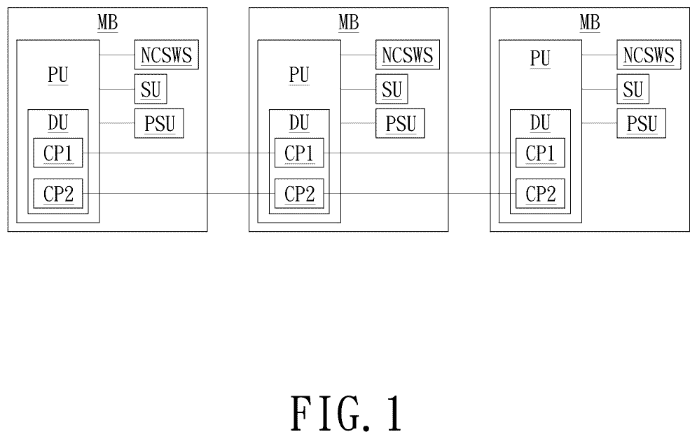

Referring to FIG. 1, FIG. 1 is a block diagram of a non-contact switch system according to an embodiment of the present invention.

In this embodiment, the non-contact switch system of the present invention includes multiple modular circuit boards MB. Each modular circuit board MB includes a processing unit PU, a non-contact switch set NCSWS, a prompt unit PSU, and a storage unit SU. The processing unit PU includes a detection unit DU, the detection unit DU includes a first common lead CP1, and a second common lead CP2. The non-contact switch set NCSWS includes multiple non-contact switches NCSW (not shown in the figure). The processing unit PU is connected to the non-contact switch set NCSWS, the prompt unit PSU, and the storage unit SU. Among the multiple processing units PU, the first common leads CP1 are interconnected, and the second common leads CP2 are interconnected.

In this embodiment, according to the non-contact switch system of the present invention, the non-contact switch set NCSWS receives the sensing signal of the sensed target ST and the processing unit PU can execute the general program (the switch detection method) of the storage unit SU, to prevent multiple non-contact switches NCSW from being touched by mistake, such that when multiple modular circuit boards MB are combined, the change, due to the identification issue of the circuit board, in the setting of the hardware or firmware (software) is unnecessary (that is, the size of the circuit board, where some of the elements can be adjusted depending on implementation situations provided that they can be still applicable to the technical architecture of the present invention without conflicts). The general program includes a single-board detection process and a multi-board detection process. The single-board detection process includes: determining whether only one non-contact switch receives a sensing signal, and entering the multi-board detection process if a determining result is yes; or determining whether only one non-contact switch receives the sensing signal, and providing, by the detection unit, a marked signal if the determining result is no. The marked signal includes a marked potential. The multi-board detection process includes: determining a first interconnected potential of the first common lead is the marked potential. The non-contact switch system of the present invention can separately determine whether the non-contact switch set NCSWS of the modular circuit board MB is touched by mistake in the single-board detection process and whether another modular circuit board MB in the multi-board detection process is touched by mistake based on the first interconnected potential of the first common lead CP1, such that even if multiple modular circuit boards MB are combined, under the condition of not changing the configuration of the hardware or firmware (software), a case can be also avoided that multiple non-contact switches NCSW in the non-contact switch system are touched by mistake.

In various s embodiments of the present invention, elements/apparatuses are represented by the same numeral reference, meaning that the functions of those elements/apparatus may include functions similar to those in other embodiments. Matters and procedural steps mentioned in various embodiments can be rearranged and combined as long as there is no conflict, and can be applied to various embodiments. The present invention is not limited to the listed embodiments.

To avoid ambiguity in noun definitions, the following describes some technical terms used in the embodiments of the present invention.

In the present invention, the non-contact switch NCSW refers to an apparatus configured to receive a sensing signal from a sensed target ST. For example, the non-contact switches NCSW may include a sensing module, and the sensing module may be a capacitive sensing module. In the case where the sensing module is a capacitive sensing module, the sensed target ST may be a human body, a part of the human body, or any object capable of changing the capacitance value sensed by the sensing module. The capacitive sensing module can sense the capacitance value of the human body, and the processing unit PU can transmit a control signal based on a change in the capacitance value to control the non-contact switch set NCSWS.

For example, the sensing module may be an infrared light sensing module and include a transmitting unit and a receiving unit. The transmitting unit can be used to emit a wireless signal to the sensed target ST, and the receiving unit can be used to receive a sensing signal. In the case where the sensing module is an infrared light sensing module, the sensed target ST may be a human body, a part of the human body, or an object capable of reflecting infrared light (for example, a reflection signal of the wireless signal) emitted by the transmitting unit. The receiving unit of the sensing module can receive the infrared light emitted by the transmitting unit and reflected by an object. In this embodiment, the sensing signal is the reflection signal of the wireless signal, and the processing unit PU can transmit a control signal based on the sensing signal (that is, the reflection signal of the wireless signal) of the sensed target received by the receiving unit, to control the non-contact switch set NCSWS.

For example, the sensing module may be an ultrasonic sensing module and include a transmitting unit and a receiving unit. In the case where the sensing module is an ultrasonic sensing module, the sensed target ST may be a human body, a part of the human body, or an object capable of reflecting an ultrasonic wireless signal (that is, a reflection signal of the wireless signal) emitted by the transmitting unit. The receiving unit of the sensing module can receive the ultrasonic wireless signal emitted by the transmitting unit and reflected by an object. The processing unit PU can transmit a control signal based on the sensing signal (that is, the reflection signal of the wireless signal) of the sensed target received by the receiving unit, to control the non-contact switch set NCSWS.

The foregoing examples are merely illustrative embodiments of the non-contact switches NCSW of the present invention. The present invention is not limited to the listed embodiments. Any apparatus capable of receiving the sensing signal of the sensed target and controlling the switch state of the non-contact switch set NCSWS via the processing unit PU can be used as the non-contact switch NCSW of the present invention.

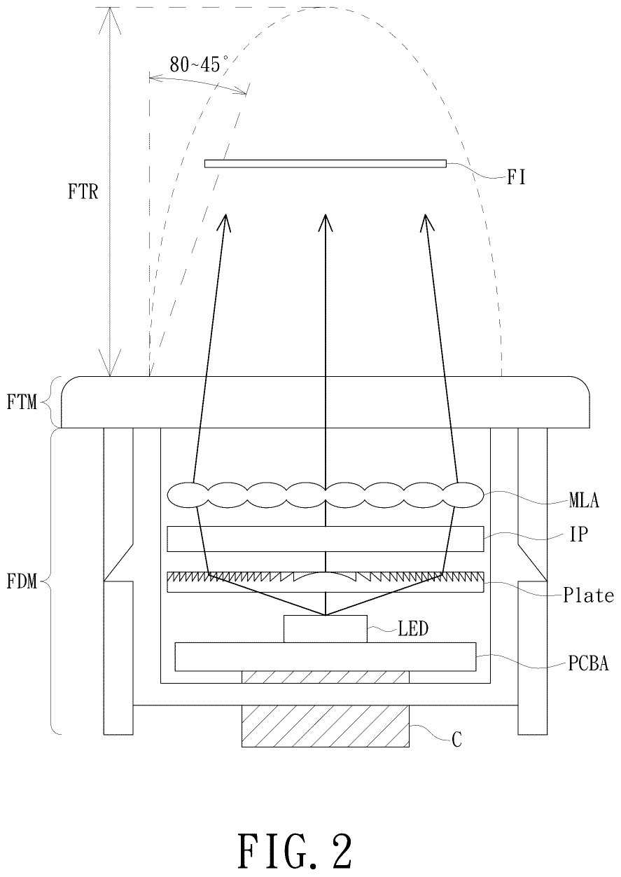

Refer to FIG. 2. In an embodiment, an example is used in which the non-contact switch NCSW in the non-contact switch set NCSWS is a floating display touch switch. FIG. 2 is a schematic diagram of a floating display touch switch according to an embodiment of the present invention. The floating display touch switch includes a floating display module FDM and a floating touch module FTM. The floating display module FDM includes a micro-lens array MLA, an imaging plate IP, a flat lens Plate, a circuit board PCBA, light-emitting diodes LED, and a connector C. The floating display touch switch in this embodiment can receive a sensing signal of a sensed target ST in a sensing region FTR via a floating touch module FTM (the floating touch module FTM includes a sensing module). The sensing region may include a sensing distance and a sensing angle. The sensing distance may be a distance, for example, 0 cm to 10 cm, from a sensing surface of the sensing module to the sensed target ST. The sensing angle may be an angle, for example, 45 degrees to 80 degrees, formed by inwardly retracting from any point on an outer edge (for example, 0 cm) of the sensing surface of the sensing module to a sensing failure point (that is, a distance at which the sensing module cannot feel the sensed target ST, for example, 10 cm).

A non-contact switch control system 1 of the present invention includes a storage unit SU, and the storage unit SU refers to an apparatus connecting the processing unit PU and configured to store the general program. For example, the storage unit SU may be a non-volatile memory, a memory card, a cache, or another apparatus with the same functions. Types of the listed storage apparatuses are only for illustration, the present invention is not limited thereto, and all storage apparatuses with the same functions can be used as the storage unit SU of the present invention. The general program refers to a program that can be applied universally to multiple modular circuit boards MB. The general program may not include a program used for distinguishing multiple modular circuit boards MB. In other words, the multiple modular circuit boards MB may be combined using exactly the same program (firmware/software).

In this embodiment, the non-contact switch system of the present invention includes a processing unit PU and a detection unit DU, where the processing unit PU is configured to execute the general program. For example, the processing unit PU may be, for example, a micro-controller unit (MCU), a central processing unit (CPU), or another apparatus with the same function, the types of listed processing units are only for illustration, and the present invention is not limited thereto. The detection unit DU may be, for example, a part of the logical circuit in the processing unit PU. The detection unit may include a first common lead CP1 and a second common lead CP2. The processing unit PU can configure potentials for the first common lead CP1 and the second common lead CP2. The default output potential is referred to as a preset potential in the present invention, and the output potential is referred to as the marked potential when it is determined that the non-contact switch NCSW is touched by mistake. The first interconnected potentials of multiple first common leads CP1 are interconnected. To be specific, when a first interconnected potential of any first common lead CP1 of any processing unit PU is configured as a marked potential, the first interconnected potentials of all the first common leads CP1 are configured as marked potentials in an interconnected manner. The second interconnected potentials of multiple second common leads CP2 are interconnected. To be specific, when a second interconnected potential of any second common lead CP2 of any processing unit PU is configured as a marked potential, the second interconnected potentials of all the second common leads CP2 are configured as marked potentials in an interconnected manner. The marked potential is prior to the preset potential. To be specific, only when all the first interconnected potentials or the second interconnected potentials are configured as default potentials, the first interconnected potential or the second interconnected potential is presented as the preset potential. When any first interconnected potential or the second interconnected potential is configured as a marked potential, the first interconnected potential or the second interconnected potential is presented as the marked potential. The default potential and marked potential can be each represented by a logical potential, and their voltage ranges are not limited in the present invention.

In the present invention, disabling refers to an action causing an element to lose its original function in the system. For example, disabling the non-contact switch set NCSWS may refer to an action causing the processing unit PU to ignore signals from the non-contact switch set NCSWS or an action that the processing unit PU sends a control signal to enable the non-contact switch set NCSWS to temporarily ignore instructions directed towards it. In an embodiment, the processing unit PU may send a stop instruction to make the transmitting unit of the non-contact switch set NCSWS stop transmitting a wireless signal. Through this, the non-contact switch set NCSWS cannot receive the reflection signal (that is, the sensing signal of the sensed target ST) of the wireless signal, so as to achieve the technical beneficial effect of avoiding a false touch by disabling the non-contact switch set NCSWS. Disabling refers to an action causing an element to lose its original function in the system (for example, the switch loses the triggering function). The present invention does not limit the implementation herein.

In this embodiment, the non-contact switch system of the present invention includes a prompt unit PSU configured to provide an operation prompt. For example, when the sensing signal of the sensed target ST is sensed in sensing regions of multiple non-contact switches NCSW at the same time point, the processing unit PU may send an instruction for disabling, such that the non-contact switch set NCSWS is not triggered. The operation prompt refers to a prompt used for informing the user of, for example, the non-contact switch set NCSWS being in a disabled state. In this embodiment, the prompt unit PSU may be an independent apparatus that is independently connected to the processing unit PU. The prompt unit PSU may be an apparatus such as a buzzer, a light-emitting diode, or a liquid crystal display. The prompt unit PSU can send prompt messages (for example, audio messages, text messages, or color messages). The PSU informs, by means of emitting sounds, illuminating LEDs of various colors, displaying text, or the like, the user that multiple non-contact switches NCSW of the non-contact switch system are being touched by mistake. After the false touch on the non-contact switch NCSW is excluded (for example, all non-contact switches NCSW do not receive the sensing signal of the sensed target ST), the non-contact switch system releases the disabling state and restores the normal operation mode.

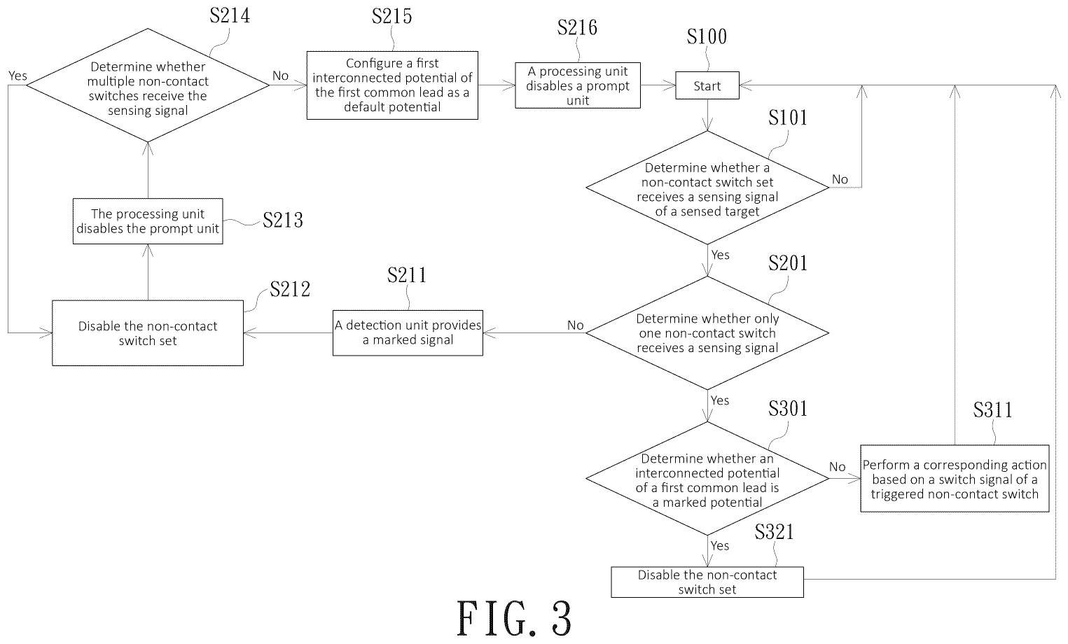

Next, refer to FIG. 3. FIG. 3 is a flowchart of steps of a switch detection method (general program) according to an embodiment of the present invention. A step process includes a single-board detection process (steps S201 to S216) and a multi-board detection process (S301 to S321), and details are described below.

The switch detection method (general program) includes the following steps:
Step S100: Start a step process and perform step S101.
Step S101: Determine whether a non-contact switch set NCSWS receives a sensing signal of a sensed target ST; and if a determining result is yes, perform step S201 to enable the general program to enter the single-board detection process; and if the determining result is no, return to step S100 until the non-contact switch set NCSWS receives the sensing signal of the sensed target ST.
Step S201: Determine whether only one non-contact switch NCSW receives the sensing signal; and if a determining result is yes, perform step S301 to enable the general program to enter the multi-board detection process; or if the determining result is no, which indicates that multiple non-contact switches NCSW in the modular circuit board MB are triggered (touched by mistake), perform step S211.
Step S211: A detection unit DU provides a marked signal, and step S212 is performed. Step S211 may further include step S2111 and/or step S2112.
Step S2111: A processing unit PU configures a first interconnected potential of the first common lead CP1 as a marked potential.
Step S2112: The processing unit PU configures the first interconnected potential of the first common lead CP1 or a second interconnected potential of a second common lead CP2 as a marked potential. Compared with configuration with the use of only the first interconnected potential of the first common lead CP1, the configuration with the additional use of the second interconnected potential of the second common lead CP2 in the present invention can reduce the instructions sent and make it quicker to determine the false touch.
Step S212: The processing unit PU disables the non-contact switch set NCSWS, and step S213 is performed.
Step S213: The processing unit PU enables a prompt unit PSU, and step S214 is performed. The processing unit PU can enable the prompt unit PSU to inform the user that the current non-contact switch system is in a disabled state.
Step S214: The processing unit PU determines whether multiple non-contact switches NCSW receive the sensing signal; and if a determining result is yes, which indicates a false touch on the non-contact switches NCSW has not been excluded, a return is made to step S212; or if the determining result is no, which indicates that the false touch on the non-contact switches NCSW has been excluded, step S215 is performed.
Step S215: The processing unit PU configures a first interconnected potential of the first common lead CP1 as a default potential, and step S216 is performed. Step S215 may further include step S2151.
Step S2151: Configure the first interconnected potential of the first common lead CP1 or the second interconnected potential of the second common lead CP2 as a default potential.
Step S216: The processing unit PU disables the prompt unit PSU, and step S100 is performed.
Step S301: The processing unit PU determines whether an interconnected potential of the first common lead CP1 is a marked potential; and if a determining result is yes, which indicates that multiple non-contact switches NCSW in another modular circuit board MB are triggered (touched by mistake), step S321 is performed; or if the determining result is no, no false touch occurred in another modular circuit board MB. Step S301 may further include step S3011.
Step S3011: The processing unit PU determines whether the first interconnected potential of the first common lead CP1 or the second interconnected potential of the second common lead CP2 is a marked potential.
Step S311: The processing unit PU performs a corresponding action based on a switch signal of a triggered non-contact switch NCSW, and a return is made to step S100. Because no false touch occurred in the modular circuit board MB and another modular circuit board MB, the processing unit PU can perform the corresponding action based on the switch signal (instruction information) of the triggered non-contact switch NCSW.
Step S321: Disable the non-contact switch set NCSWS and return to step S100. Because a false touch occurred in another modular circuit board MB, the processing unit PU disables the non-contact switch set NCSWS and sends a corresponding switch signal after a false touch state is excluded.

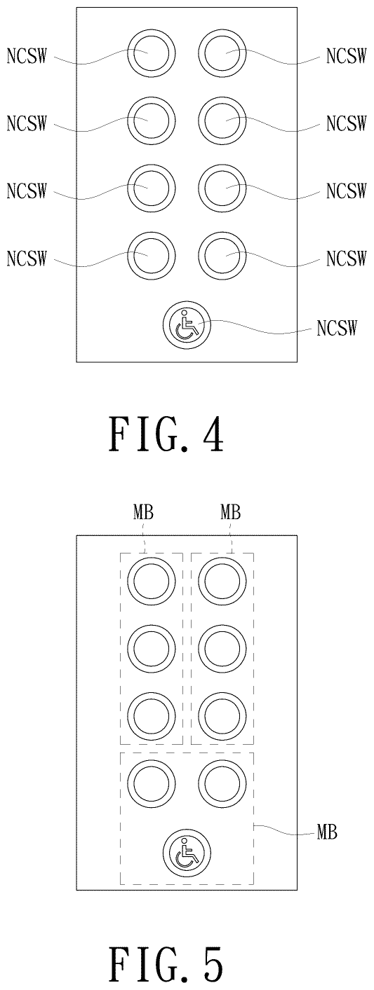

Next, refer to FIGS. 4 to 6. FIGS. 4 to 6 are schematic diagrams of a non-contact switch system being applied to an elevator system according to an embodiment of the present invention.

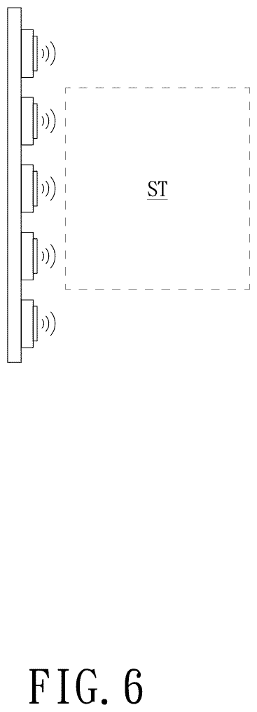

In FIG. 4, an operation panel of the elevator system is shown. Referring to FIG. 5, the operation panel is assembled by combining three modular circuit boards MB with slightly different circuit board sizes and element configurations. However, according to the foregoing embodiment of the present invention, in this embodiment, only two different spare circuit boards are prepared for the modular circuit board MB, and the same firmware (software) is burned onto the modular circuit board MB. As shown in FIG. 6, when a sensed target ST with a large cross-sectional area touches multiple non-contact switches NCSW by mistake, the non-contact switch system can perform the switch detection method (general program) in FIG. 3, to avoid the case where multiple non-contact switches NCSW in the non-contact switch system are touched by mistake.

In summary, according to the modular circuit board, the non-contact switch system, and the switch detection method of the present invention, multiple processing units can be interconnected using the common leads of the detection units, and it is determined whether the modular circuit board is touched by mistake in the single-board detection process and whether another modular circuit board is touched by mistake in the multi-board detection process. With the use of the foregoing architecture, in the present invention, when multiple modular circuit boards are combined for use, the primary-secondary relation between circuit boards does not need to be distinguished, and the same software/firmware can be used to correspond to the combination configuration of multiple circuit boards without the need to burn different software/firmware onto the modular circuit boards. In this way, the present invention can achieve technical beneficial effects such as quick replacement and a decrease in maintenance time and can reduce the inventory of spare circuit boards and increase the replaceability between the modular circuit boards.

What is claimed is:

1. A modular circuit board, comprising:
a non-contact switch set, comprising a plurality of non-contact switches configured to receive a sensing signal of a sensed target;
a storage unit, configured to store a general program; and
a processing unit, connected to the non-contact switch set and the storage unit and configured to perform the general program, wherein the processing unit comprises a detection unit, and the detection unit comprises a first common lead;
wherein the general program comprises a single-board detection process and a multi-board detection process;
wherein the single-board detection process comprises:
determining whether only one non-contact switch receives the sensing signal, and entering the multi-board detection process when it is determined that only one non-contact switch receives the sensing signal; or
determining whether only one non-contact switch receives the sensing signal, and providing, by the detection unit, a marked signal when it is determined that not only one non-contact switch receives the sensing signal, wherein the marked signal comprises a marked potential;
wherein the multi-board detection process comprises:
determining whether a first interconnected potential of the first common lead is the marked potential.

2. The modular circuit board according to claim 1, wherein the detection unit comprises a second common lead, and the single-board detection process further comprises:
configuring the first interconnected potential of the first common lead or a second interconnected potential of the second common lead as the marked potential.

3. The modular circuit board according to claim 1, wherein the single-board detection process further comprises:
disabling the non-contact switch set.

4. The modular circuit board according to claim 3, wherein the single-board detection process further comprises:
enabling a prompt unit.

5. The modular circuit board according to claim 1, wherein the single-board detection process further comprises:
configuring the first interconnected potential of the first common lead as a default potential.

6. The modular circuit board according to claim 2, wherein the single-board detection process further comprises:
configuring the first interconnected potential of the first common lead or the second interconnected potential of the second common lead as a default potential.

7. The modular circuit board according to claim 1, wherein the multi-board detection process further comprises:
disabling the non-contact switch set.

8. A non-contact switch system, comprising:
a plurality of modular circuit boards according to claim 1, wherein the first common leads are interconnected.

9. A switch detection method, suitable for a non-contact switch system, wherein the non-contact switch system comprises a plurality of modular circuit boards, each of the modular circuit boards comprises a non-contact switch set and a processing unit, the processing unit comprises a detection unit, the detection unit comprises a first common lead, the modular circuit boards are interconnected via the first common leads, and the switch detection method comprises a single-board detection process and a multi-board detection process;
wherein the single-board detection process comprises:
determining, by the processing unit, whether only one non-contact switch receives a sensing signal of a sensed target, and entering the multi-board detection process when it is determined that only one non-contact switch receives the sensing signal; or
determining, by the processing unit, whether only one non-contact switch receives the sensing signal, and providing, by the detection unit, a marked signal when it is determined that not only one non-contact switch receives the sensing signal, wherein the marked signal comprises a marked potential;
wherein the multi-board detection process comprises:
determining, by the processing unit, whether a first interconnected potential of the first common lead is the marked potential.
